(19) United States
(12) Patent Application Publication
(10) Pub. No.: US 2024/0072078 A1
(43) Pub. Date: Feb. 29, 2024

(54) ELECTRONIC DEVICE

(71) Applicant: InnoCare Optoelectronics Corporation, Tainan City (TW)

(72) Inventors: Ting-Yu Chen, Tainan City (TW); Chin-Chi Chen, Tainan City (TW)

(73) Assignee: InnoCare Optoelectronics Corporation, Tainan City (TW)

(21) Appl. No.: 18/349,185

(22) Filed: Jul. 10, 2023

(30) Foreign Application Priority Data
Aug. 25, 2022 (TW) 111131989

(51) Int. Cl. H01L 27/146

(52) U.S. Cl. CPC H01L 27/14607; H01L 27/1462; H01L 27/14663

(57) ABSTRACT

An electronic device including a substrate, a gate line, a switch element, and a photodetector is provided. The gate line is disposed on the substrate. The switch element is disposed on the substrate and is electrically connected to the gate line. The photodetector is disposed on the substrate and electrically connected to the switch element. The photodetector includes a first semiconductor. In a cross-sectional view of the electronic device, a sidewall of the first semiconductor and the gate line are spaced from each other by a first distance. The first distance is greater than or equal to 2 micrometers and less than or equal to 6 micrometers.

### CROSS-REFERENCE TO RELATED APPLICATION

This application claims the priority benefit of Taiwan application serial no. 111131989, filed on Aug. 25, 2022. The entirety of the above-mentioned patent application is hereby incorporated by reference herein and made a part of this specification.

### BACKGROUND

### Technical Field

The disclosure relates to an electronic device; more particularly, the disclosure relates to an electronic device which may solve an issue of current leakage in a photodetector or may improve quality of detected images.

### Description of Related Art

Electronic devices, such as X-ray detectors, may be configured for medical inspection imaging and/or non-destructive industrial inspection. The penetration characteristics of X-rays allow the X-ray detectors to perform inspections without damaging the inspected objects to be widely applied to personal biological inspections, security check of airport luggage or passengers, and so on. The quality requirements for the electronic devices are also increasing day by day.

### SUMMARY

The disclosure provides an electronic device which may solve an issue of current leakage in a photodetector or may improve quality of detected images.

According to an embodiment of the disclosure, an electronic device including a substrate, a gate line, a switch element, and a photodetector is provided. The gate line is disposed on the substrate. The switch element is disposed on the substrate and electrically connected to the gate line. The photodetector is disposed on the substrate and electrically connected to the switch element, and the photodetector includes a semiconductor. In a cross-sectional view of the electronic device, one sidewall of the semiconductor and the gate line are spaced from each other by a first distance, and the first distance is greater than or equal to 2 micrometers and less than or equal to 6 micrometers.

In order to make the above-mentioned features and advantages of the disclosure comprehensible, embodiments accompanied with drawings are described in detail below.

### BRIEF DESCRIPTION OF THE DRAWINGS

The accompanying drawings, which are included to provide a further understanding of the disclosure, are incorporated in and constitute a part of this specification. The drawings illustrate embodiments of the disclosure and, together with the description, serve to explain the principles of the disclosure.

FIG. 1 is a schematic cross-sectional view illustrating an electronic device according to an embodiment of the disclosure.

FIG. 2 is a schematic top view illustrating the electronic device depicted in FIG. 1.

FIG. 3 is a schematic cross-sectional view illustrating the electronic device depicted in FIG. 2 along a sectional line I-I′.

FIG. 4 is a schematic enlarged view illustrating a region R1 in FIG. 3.

FIG. 5 is a schematic cross-sectional view illustrating the electronic device depicted in FIG. 2 along a sectional line II-II′.

### DESCRIPTION OF THE EMBODIMENTS

The disclosure will be understood by reference to the following detailed description when considered in connection with the accompanying drawings. It is to be noted that, for ease of understanding and simplicity of the drawings, some of the drawings of the disclosure only illustrate a part of an electronic device, and specific elements in the drawings are not drawn according to actual scale. In addition, the number and size of each element in the drawings are only for schematic purposes and are not intended to limit the scope of the disclosure.

In the following description and claims, the terminologies such as “include” and “comprise” are used in an open-ended fashion and thus should be interpreted to mean “including but not limited to . . . ”.

It will be understood that when an element or layer is referred to as being “on” or “connected to” another element or layer, it may be directly on or directly connected to the another element or layer, or an intervening element or layer may be present between the two (indirect case). In contrast, when an element or layer is referred to as being “directly on” or “directly connected to” another element or layer, there is no intervening element or layer between the two.

Although terminologies such as “first”, “second”, “third” and the like may be used to describe various elements, the elements are not limited to these terminologies. These terminologies are used only to distinguish one element from another in the specification. The same terminologies are not necessarily used in the claims as in the description and may be replaced with first, second, third and the like according to the order in which the elements are stated in the claims. Therefore, a first element in the following description may be a second element in the claims.

Terminologies such as “about”, “approximately”, “substantially,” and “roughly” as used herein usually mean within 10%, 5%, 3%, 2%, 1%, or 0.5% of a given value or range. Every quantity given herein is an approximate quantity, that is, the meanings of the terminologies such “about”, “approximately”, “substantially” and “roughly” are implied even if the terminologies are not specifically used. Expressions such as “range of a first value to a second value” and “range of between a first value and a second value” mean that the range includes the first value, the second value, and other values therebetween.

In some embodiments of the disclosure, unless specifically defined, terminologies regarding bonding and connection, such as “connected” and “interconnected”, may mean that two structures are in direct contact, or are not in direct contact and have other structures disposed therebetween. The terminologies regarding bonding and connection may also include a case where both structures are movable or both structures are fixed. In addition, the terminology “electronically connected” or “coupled” includes any direct and indirect electrical connection means. That is, when an element is said to be “electrically connected to another element (or a variant thereof)”, it may be directly connected or electrically connected to the another element or indirectly connected or electrically connected through one or more elements to the another element.

In this disclosure, measurement of length, width, thickness, height, or area, or measurement of distance or interval between elements may be done by applying an optical microscope (OM), a scanning electron microscope (SEM), an alpha step (α-step) profilometer, an ellipsometer, or any other appropriate measurement method. Specifically, according to some embodiments, the SEM may be applied to obtain a cross-sectional image of a to-be-measured element, and the width, the thickness, the height, or the area of each element or the distance or the interval between the elements may be measured, which should not be construed as a limitation in the disclosure.

The electronic device disclosed in the embodiments of the disclosure may include a display device, a backlight device, an antenna device, a sensing device, or a tiled device. The sensing device includes but may not be limited to an X-ray sensor or a fingerprint identification device, for instance. Besides, the electronic device may include a bendable or flexible electronic device. The display device may include a non-self-luminous display device or a self-luminous display device. The electronic device may include, for instance, liquid crystal, light emitting diode, fluorescence, phosphor, quantum dot (QD), other suitable display media, or a combination of the foregoing. The antenna device may include a liquid crystal antenna device or a non-liquid crystal antenna device, and the sensing device may include but may not be limited to a sensing device for sensing capacitance, light, electromagnetic waves, heat, or ultrasonic waves. In the disclosure, the electronic device may include electronic elements, and the electronic elements may include passive elements and active elements, such as capacitors, resistors, inductors, diodes, transistors, controllers, light emitting units, photo-sensing units, driving units, antenna units, and the like. The diodes may include light emitting diodes or photodiodes. The light emitting diodes may include but may not be limited to, for instance, organic light emitting diodes (OLED), sub-millimeter light emitting diodes (mini LED), micro light emitting diodes (micro LED), or quantum dot light emitting diodes (quantum dot LED). The tiled device may include but may not be limited to, for instance, a display tiled device or an antenna tiled device. It should be noted that the electronic device may be any arrangement and combination of the foregoing, but not limited to thereto. In addition, the appearance of the electronic device may be in a rectangular shape, a circular shape, a polygonal shape, a shape with curved edges, or other suitable shapes. The electronic device may have peripheral systems, such as a driving system, a control system, a light source system, a rack system, and the like, so as to support a display device, an antenna device, a wearable device (e.g., including augmented reality or virtual reality), an in-vehicle device (e.g., including car windshield), a tiled device, or a sensing device. The electronic device will be applied to illustrate the disclosure hereinafter, but the disclosure is not limited thereto.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

Reference will now be made in detail to the exemplary embodiments of the disclosure, and examples of the exemplary embodiments are illustrated in the accompanying drawings. Whenever possible, the same reference numbers are used in the drawings and descriptions to indicate the same or similar parts.

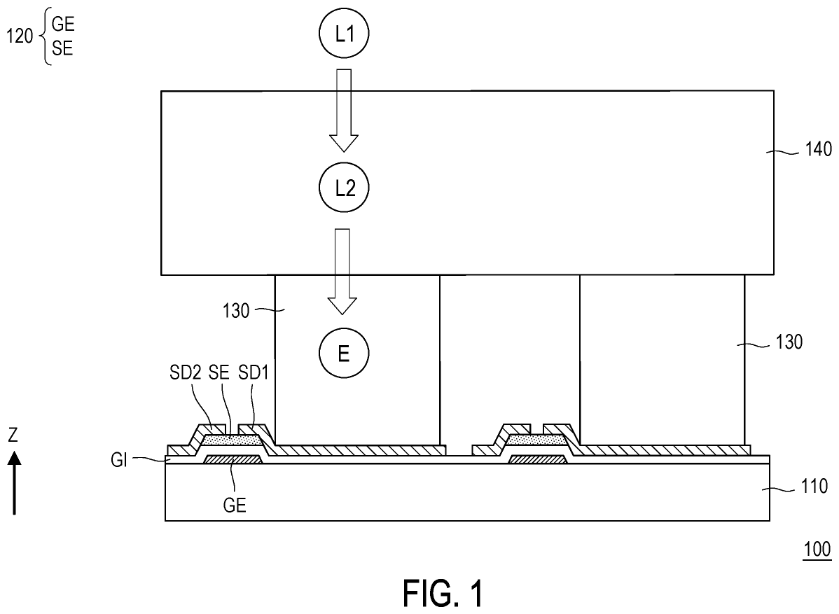

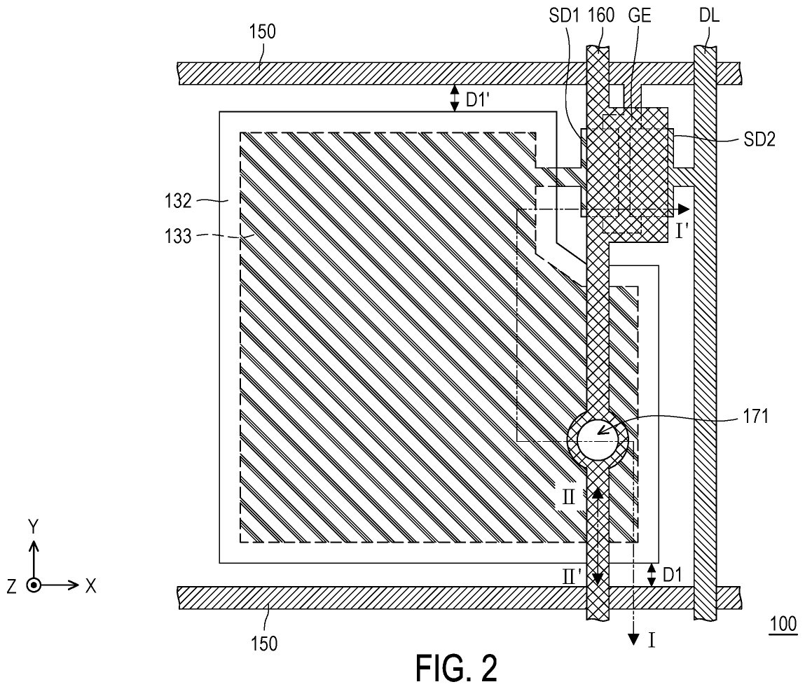

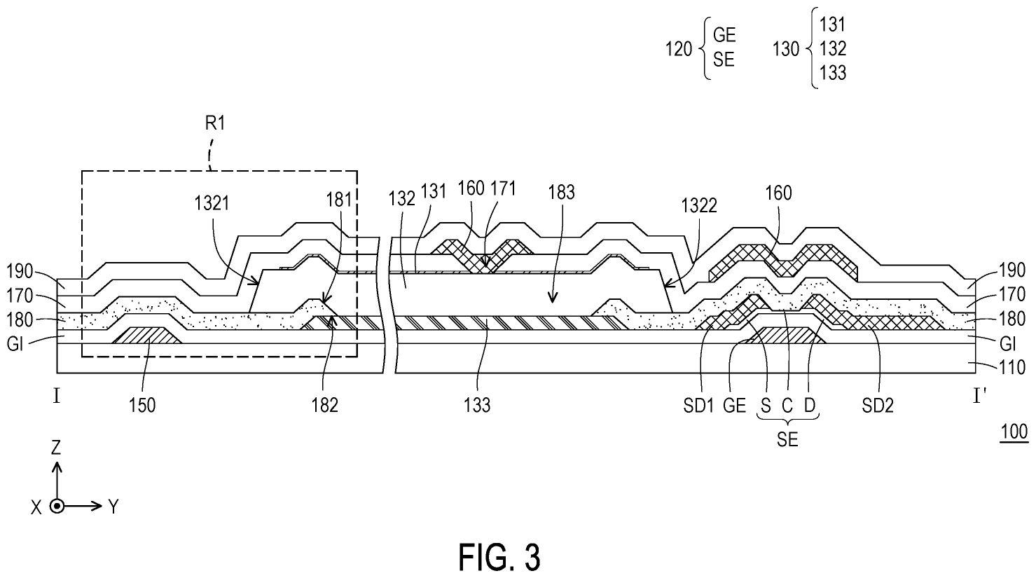

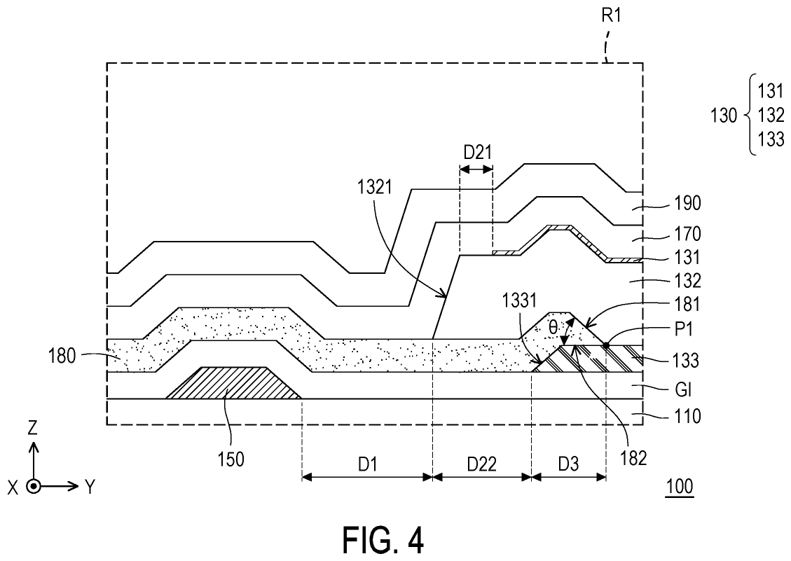

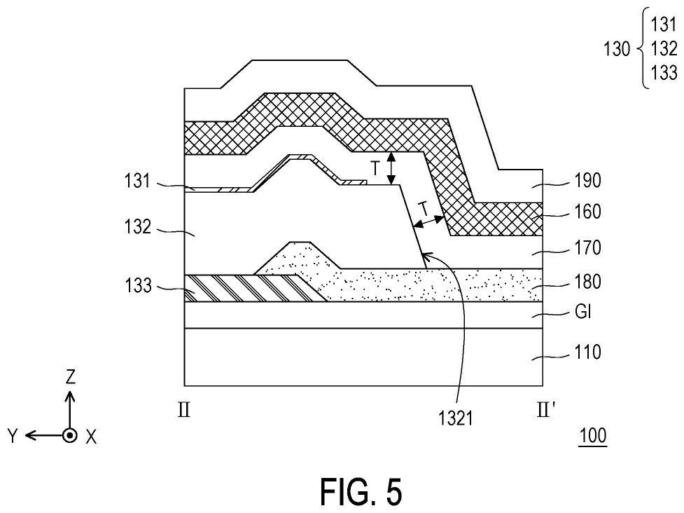

FIG. 1 is a schematic cross-sectional view illustrating an electronic device according to an embodiment of the disclosure. In this embodiment, the electronic device is, for instance, a sensing device, especially referring to an X-ray sensing device for detecting X-rays, which should however not be construed as a limitation in the disclosure. In other embodiments, when the electronic device refers to a display device or an antenna device, the electronic device may not include any scintillator, which should however not be construed as a limitation in the disclosure. FIG. 2 is a schematic top view illustrating the electronic device depicted in FIG. 1. FIG. 3 is a schematic cross-sectional view illustrating the electronic device depicted in FIG. 2 along a sectional line I-I′. FIG. 4 is a schematic enlarged view illustrating a region R1 in FIG. 3. FIG. 5 is a schematic cross-sectional view illustrating the electronic device depicted in FIG. 2 along a sectional line II-II′. For clarity of the accompanying drawings and for the illustrative purpose, some elements in the electronic device 100 are omitted from FIG. 2, e.g., a scintillator 140 is not shown in FIG. 2.

With reference to FIG. 1, an electronic device 100 provided in this embodiment may include a substrate 110, a switch element 120, and a photodetector 130. Here, the switch element 120 and the photodetector 130 are both disposed on the substrate 110. In another embodiment, the electronic device 100 may further include a scintillator 140 disposed on the substrate 110, and the photodetector 130 is disposed between the scintillator 140 and the substrate 110. In a cross-sectional view of the electronic device 100 (as shown in FIG. 1), the scintillator 140 and the photodetector 130 may be overlapped in a normal direction of the substrate 110 (i.e., a direction Z).

In this embodiment, the photodetector 130 may be configured to detect the intensity of electromagnetic waves (e.g., X-rays or visible light) and generate an electrical signal E. In another embodiment, the scintillator 140 may be adapted to convert an X-ray L1 into a visible light L2. The photodetector 130 may be configured to detect the visible light L2 and generate the electrical signal E according to the intensity of an optical signal of the visible light L2 (e.g., the number of photons of the visible light L2). The switch element 120 is electrically connected to the photodetector 130 and may be configured to receive the electrical signal E and transmit the electrical signal E to other devices.

With reference to FIG. 2 and FIG. 3, the electronic device 100 provided in this embodiment may not only include the substrate 110, the switch element 120, and the photodetector 130 but also include a gate line 150, which should however not be construed as a limitation in the disclosure.

Specifically, in this embodiment, the substrate 110 may be, for instance, a rigid substrate, a flexible substrate, or a combination of the foregoing. For instance, a material of the substrate 110 may include glass, quartz, sapphire, ceramics, polycarbonate (PC), polyimide (PI), polyethylene terephthalate (PET), other suitable substrate materials, or a combination of the foregoing, which should however not be construed as a limitation in the disclosure. In addition, in this embodiment, a direction X, a direction Y, and the direction Z are different from one another, respectively. For instance, the direction X is, for instance, an extension direction of the gate line 150, the direction Y is, for instance, an extension direction perpendicular to the gate line 150, and the direction Z is, for instance, the normal direction of the substrate 110, where the direction X is substantially perpendicular to the direction Y, and the direction X and the direction Y are substantially perpendicular to the direction Z, respectively, which should however not be construed as a limitation in the disclosure.

In this embodiment, the switch element 120 is disposed on the substrate 110. The switch element 120 includes a gate electrode GE and a semiconductor SE. The gate electrode GE is disposed on the substrate 110. The electronic device 100 in another embodiment may further include a gate insulation layer GI, a data line DL, a conductive wire 160, a first insulation layer 170, a second insulation layer 180, and a third insulation layer 190, which should however not be construed as a limitation in the disclosure. The gate insulation layer GI is disposed between the gate line 150 and the data line DL and may be disposed on the gate electrode GE to cover the gate electrode GE. The semiconductor SE is disposed on the gate insulation layer GI and corresponding to the gate electrode GE. The semiconductor SE includes a source region S, a channel region C, and a drain region D, and the channel region C is located between the source region S and the drain region D. In this embodiment, a material of the semiconductor SE may include an amorphous silicon semiconductor, a low temperature polysilicon (LTPS) semiconductor, a metal oxide semiconductor, e.g., indium gallium zinc oxide (IGZO), other suitable materials, or a combination of the above, which should however not be construed as a limitation in the disclosure. In another embodiment, the material of the semiconductor SE of different switch elements 120 may be different. For instance, the semiconductor SE of one switch element 120 includes the LTPS semiconductor, and the semiconductor SE of another switch element 120 includes the metal oxide semiconductor, which should however not be construed as a limitation in the disclosure.

In some embodiments, the switch element 120 further includes a source electrode 5131 and a drain electrode SD2. The source electrode SD1 and the drain electrode SD2 are respectively disposed on the semiconductor SE. The source electrode SD1 and the drain electrode SD2 may be electrically connected to the source region S and the drain region D of the semiconductor SE, respectively. In this embodiment, the switch element 120 may be, for instance, a transistor, such as a bottom-gate type transistor, which should however not be construed as a limitation in the disclosure. In some embodiments, the switch element may also be a top-gate type transistor, a double-gate type transistor, or any other suitable transistor, which should however not be construed as a limitation in the disclosure.

In some embodiments, the gate line 150, the data line DL, and the conductive wire 160 are respectively disposed on the substrate 110. The gate line 150 may intersect with the data line DL, and the gate line 150 may intersect with the conductive wire 160. The gate line 150 may be electrically connected to the gate electrode GE of the switch element 120, and the data line DL may be electrically connected to the drain electrode SD2 of the switch element 120.

In some embodiments, the photodetector 130 is disposed on the substrate 110 and disposed on the gate insulation layer GI. The photodetector 130 includes the semiconductor 132. In another embodiment, the photodetector 130 may further include a first electrode 131 and a second electrode 133, and the semiconductor 132 is disposed between the first electrode 131 and the second electrode 133. Here, a material of the first electrode 131 may include a transparent conductive material, such as IGZO, indium tin oxide (ITO), indium zinc oxide (IZO), indium oxide, zinc oxide, tin oxide, other suitable materials, or a combination of the above, which should however not be construed as a limitation in the disclosure. The second electrode 133 may have a single-layer structure or a multi-layer structure, and a material of the second electrode 133 may include a transparent conductive material or a non-transparent conductive material, such as IGZO, ITO, indium oxide, zinc oxide, tin oxide, a metal material (e.g., aluminum, molybdenum, copper, titanium, silver, and so forth), other suitable materials, or a combination of the above, which should however not be construed as a limitation in the disclosure. For instance, the semiconductor 132 may include a stacked structure that has a p-type semiconductor, an intrinsic semiconductor, and an n-type semiconductor (e.g., a PIN photodiode), which should however not be construed as a limitation in the disclosure. In this embodiment, the semiconductor 132 may generate charges due to the irradiation of the visible light L2 and accordingly generate the electrical signal E, which should however not be construed as a limitation in the disclosure.

In some embodiments, the second electrode 133 is disposed on the gate insulation layer GI. The second insulation layer 180 is disposed on the second electrode 133, the source electrode SD1, and the drain electrode SD2. The second insulation layer 180 has a first surface 181, a second surface 182 opposite to the first surface 181, and an opening 183, where the opening 183 may expose a portion of the second electrode 133. The semiconductor 132 is disposed on the second insulation layer 180 and in the opening 183, so that the semiconductor 132 may be electrically connected to the second electrode 133. The first electrode 131 is disposed on the semiconductor 132, and the first electrode 131 may be electrically connected to the semiconductor 132. Besides, in this embodiment, the photodetector 130 may be electrically connected to the switch element 120. In some embodiments, the semiconductor 132 of the photodetector 130 may be electrically connected to the source electrode SD1 of the switch element 120 through the second electrode 133.

In some embodiments not shown in the drawings, the second electrode 133 may include a plurality of layers; for instance, the second electrode 133 may have a double-layer structure including a first layer and a second layer. The first layer is disposed on the second layer, and the first layer may be in contact with and electrically connected to the semiconductor. Here, a material of the first layer may include, for instance, molybdenum nitride, and a material of the second layer may include, for instance, aluminum, which should however not be construed as a limitation in the disclosure. In some embodiments, when the opening 183 of the second insulation layer 180 is formed by performing an etching process, damages to a surface of the first layer by the etching process are less prevalent (i.e., the damage resulting from the etching process to the first layer is approximately 0 angstroms). Thereby, a surface of the second electrode 133 (i.e., the surface of the first layer in contact with the semiconductor) may be relatively flat, so as to reduce the number of defects due to the unevenness of the surface of the second electrode 133 when the semiconductor 132 is formed. As such, charges accumulated because of the defects during the operation of the semiconductor may be reduced.

In this embodiment, the first insulation layer 170 is disposed on the first electrode 131. The first insulation layer 170 has an opening 171, and the opening 171 may expose a portion of the first electrode 131. The conductive wire 160 is disposed on the first insulation layer 170, so that the first insulation layer 170 may be located between the conductive wire 160 and the first electrode 131 of the photodetector 130. The conductive wire 160 may be further electrically connected to the first electrode 131 through the opening 171 of the first insulation layer 170; in other words, the conductive wire 160 may be electrically connected to the photodetector 130.

In this embodiment, the third insulation layer 190 is disposed on the conductive wire 160. Here, the first insulation layer 170, the second insulation layer 180, and the third insulation layer 190 may respectively have a single-layer structure or a multi-layer structure and may include an organic material (e.g., polymethyl methacrylate), an inorganic material (e.g., silicon nitride, silicon oxide, or silicon oxynitride), or a combination of the above-mentioned structures, which should however not be construed as a limitation in the disclosure.

Although the scintillator 140 in the electronic device 100 is omitted from FIG. 2, in some embodiments, in a top view of the electronic device 100, the scintillator 140 and the photodetector 130 may be overlapped.

With reference to FIG. 2, FIG. 3, and FIG. 4 (i.e., an enlarged view of the region R1 in FIG. 3), in any cross-sectional view of the electronic device 100, a sidewall 1321 of the semiconductor 132 and the gate line 150 are spaced from each other by a first distance D1. The first distance D1 is, for instance, the minimum distance between the sidewall 1321 of the semiconductor 132 (i.e., a sidewall of the semiconductor 132 adjacent to the gate line 150) and the gate line 150, which is measured along a direction (e.g., the direction Y, which should however not be construed as a limitation in the disclosure). In this embodiment, an electric field generated by a voltage applied to the gate line 150 poses an impact on the number of charges on the sidewall 1321 of the semiconductor 132. Hence, the probability of current leakage during the operation of the semiconductor 132 may be reduced by adjusting the first distance D1 to be greater than or equal to 2 micrometers (μm) and less than or equal to 6 μm (i.e., 2 μm≤D1≤6 μm), so as to improve quality of detected images, which should however not be construed as a limitation in the disclosure. In some embodiments, the first distance D1 may be, for instance, greater than or equal to 3 μm and less than or equal to 5 μm (i.e., 3 μm≤D1≤5 μm). However, when the first distance D1 is less than 3 μm, the electric field generated by the voltage applied to the gate line 150 increases the impact on the number of charges on the sidewall 1321 of the semiconductor 132, so that the probability of the current leakage during the operation of the semiconductor 132 is increased; when the first distance D1 is greater than 5 μm, the area of the semiconductor 132 is reduced, which leads to a decrease in an aperture of the electronic device 100. In some embodiments, a first distance D1′ may be, for instance, the minimum distance measured along the direction Y between another sidewall (i.e., opposite to the sidewall 1321) of the semiconductor 132 and the gate line 150, and the first distance D1′ may be, for instance, greater than or equal to 3 μm and less than or equal to 5 μm (i.e., 3 μm≤D1′≤5 μm).

In some embodiments, the first electrode 131 of the photodetector 130 and the sidewall 1321 of the semiconductor 132 are spaced from each other by a second distance D21, and/or the second electrode 133 and the sidewall 1321 of the semiconductor 132 are spaced from each other by a second distance D22. With reference to FIG. 3 and FIG. 4, according to some embodiments, in any cross-sectional view of the electronic device 100, the first electrode 131 and the sidewall 1321 of the semiconductor 132 are spaced from each other by the second distance D21; in another embodiment, the second electrode 133 and the sidewall 1321 of the semiconductor 132 are spaced from each other by the second distance D22; in still another embodiment, the first electrode 131 and the second electrode 133 are spaced from the sidewall 1321 of the semiconductor 132 by the second distance D21 and the second distance D22, respectively. The second distance D21 is, for instance, the minimum distance measured along the direction Y between the first electrode 131 and the sidewall 1321 of the semiconductor 132, and the second distance D22 is, for instance, the minimum distance measured along the direction Y between the second electrode 133 and the sidewall 1321 of the semiconductor 132. In this embodiment, since the electric field generated during operation of the first electrode 131 and/or the second electrode 133 poses an impact on the number of charges on the sidewall 1321 of the semiconductor 132, the issue of current leakage during the operation of the semiconductor 132 may be solved to a certain degree by adjusting the second distance D21 or the second distance D22 to be, for instance, greater than or equal to 0.5 μm and less than or equal to 6 μm (i.e., 0.5 μm≤D21≤6 μm, or 0.5 μm≤D22≤6 μm), so as to improve the quality of the detected images, which should however not be construed as a limitation in the disclosure. In some embodiments, the second distance D21 or the second distance D22 may be, for instance, greater than or equal to 1.5 μm and less than or equal to 4.5 μm (i.e., 1.5 μm≤D2≤4.5 μm, or 1.5 μm≤D2a≤4.5 μm). When the second distance D21 or the second distance D22 is less than 1.5 μm, the impact on the number of charges on the sidewall 1321 of the semiconductor 132, which results from the electric field generated by the first electrode 131 and/or the second electrode 133, is increased, and accordingly the probability of the current leakage during the operation of the semiconductor 132 is increased; when the second distance D21 or the second distance D22 is greater than 4.5 μm, the area of the first electrode 131 and/or the second electrode 133 is reduced, which leads to a reduction of a utilization rate of the semiconductor 132 by the electric field generated between the first electrode 131 and the second electrode 133.

With reference to FIG. 3 and FIG. 4, according to some embodiments, in any cross-sectional view of the electronic device 100, there is an included angle θ between the first surface 181 and the second surface 182 of the second insulation layer 180. The first surface 181 is, for instance, a surface of the second insulation layer 180 away from the substrate 110, the second surface 182 is, for instance, a surface of the second insulation layer 180 close to the substrate 110, and the included angle θ is, for instance, an included angle at an intersection between the first surface 181 and the second surface 182. In this embodiment, the included angle θ between the first surface 181 and the second surface 182 may be, for instance, greater than 0 degrees (°) and less than or equal to 12° (i.e., 0°<θ≤12°), so that the flatness of the semiconductor 132 may be improved. As such, the probability of generating the defects while the semiconductor 132 is being formed may be reduced, the probability of the current leakage during the operation of the semiconductor 132 may also be reduced, and accordingly the quality of the detected images may be improved, which should however not be construed as a limitation in the disclosure. In some embodiments, the included angle θ between the first surface 181 and the second surface 182 may be, for instance, greater than 2° and less than or equal to 10° (i.e., 2°<θ≤10°). When the included angle θ is less than 2°, the ability of controlling electrons in the semiconductor 132 by the electric field generated between the first electrode 131 and the second electrode 133 is reduced, and a utilization rate of the photodetector 130 is thus affected; when the included angle θ is greater than 12°, more defects may be generated while the semiconductor 132 is being formed, and the probability of the current leakage during the operation of the semiconductor 132 is increased.

With reference to FIG. 3 and FIG. 4, according to some embodiments, in any cross-sectional view of the electronic device 100, there is an intersection P1 between the first surface 181 and the second surface 182 of the second insulation layer 180, and the intersection P1 and an edge 1331 of the second electrode 133 (i.e., an edge of the second electrode 133 adjacent to the gate line 150) is spaced from each other by a third distance D3. The intersection P1 is, for instance, an intersection between the first surface 181 and the second surface 182, and the third distance D3 is, for instance, the maximum distance measured along the direction Y between the intersection P1 and the edge 1331 of the second electrode 133. In this embodiment, the third distance D3 may be, for instance, greater than or equal to 2 μm and less than or equal to 5.5 μm (i.e., 2 μm≤D3≤5.5 μm), so as to allow the electric field generated between the first electrode 131 and the second electrode 133 to have an improved control ability to the charges in the semiconductor 132 and improve the utilization rate of the photodetector 130, which should however not be construed as a limitation in the disclosure. When the third distance D3 is less than 2 μm, the included angle θ between the first surface 181 and the second surface 182 is increased, which may increase the defects of the semiconductor 132 and the probability of the current leakage during the operation of the semiconductor 132; when the third distance D3 is greater than 5.5 μm, a region in the semiconductor 132 where the electrons may be effectively utilized is reduced, and thus the utilization rate of the photodetector 130 is reduced.

Please refer to FIG. 5, which is a schematic cross-sectional view illustrating the electronic device depicted in FIG. 2 along a sectional line II-II. In the cross-sectional view of the electronic device 100, the first insulation layer 170 has a thickness T. The thickness T is, for instance, the minimum distance between the sidewall 1321 of the semiconductor 132 and the conductive wire 160 adjacent to the semiconductor 132 or the minimum distance along the direction Z between the semiconductor 132 and the conductive wire 160. In this embodiment, an electric field generated during the operation of the conductive wire 160 poses an impact on the number of charges on the sidewall 1321 of the semiconductor 132 or the number of charges in a region of the semiconductor 132 adjacent to the sidewall 1321, and therefore the probability of the current leakage during the operation of the semiconductor 132 may be reduced by adjusting the thickness T of the first insulation layer 170 to be greater than or equal to 0.5 μm and less than or equal to 3 μm (i.e., 0.5 μm≤T≤3 μm), so as to improve the quality of the detected images, which should however not be construed as a limitation in the disclosure. In some embodiments, the thickness T of the first insulation layer 170 may be, for instance, greater than or equal to 1 μm and less than or equal to 2.5 μm (i.e., 1 μm≤T≤2.5 μm). When the thickness T is less than 1 μm, the impact on the number of charges on the semiconductor 132, which results from the electric field generated during the operation of the conductive wire 160, may be increased, thus worsening the problem of the current leakage during the operation of the semiconductor 132; when the thickness T is greater than 5 μm, the manufacturing cost is increased.

To sum up, in the electronic device provided in one or more embodiments of the disclosure, since the first distance between the sidewall of the semiconductor of the photodetector and the gate line may be greater than or equal to 2 μm and less than or equal to 6 μm, the impact on the number of charges on the sidewall of the semiconductor, which results from the electric field generated by the voltage applied on the gate line, may be lessened, and the probability of the current leakage during the operation of the semiconductor may be reduced (i.e., the probability of the current leakage of the photodetector may be reduced), and the quality of the detected images may be further improved. Since the second distance between the first electrode and/or second electrode of the photodetector and the sidewall of the semiconductor may be greater than or equal to 0.5 μm and less than or equal to 6 μm, the impact on the number of charges on the sidewall of the semiconductor, which results from the electric field generated during the operation of the first electrode and/or the second electrode, may be lessened, and the probability of the current leakage during the operation of the semiconductor may be reduced. Since the included angle between the first surface and the second surface of the second insulation layer may be greater than 0° and less than or equal to 12°, the flatness of the semiconductor of the photodetector may be improved, so as to reduce the probability of generating the defects while the semiconductor is being formed and further reduce the probability of the current leakage during the operation of the semiconductor. Since the third distance between the intersection of the first surface and the second surface of the second insulation layer and the edge of the second electrode may be greater than or equal to 2 μm and less than or equal to 5.5 μm, the electric field generated between the first electrode and the second electrode may have the improved ability of controlling the charges in the semiconductor. Since the thickness of the first insulation layer may be greater than or equal to 0.5 μm and less than or equal to 3 μm, the probability of the current leakage during the operation of the semiconductor, which results from the electric field generated during the operation of the conductive wire, may be reduced.

Finally, it should be noted that the above embodiments serve to illustrate rather than limiting the technical solutions of the disclosure. Although the disclosure has been described in detail with reference to the above embodiments, persons skilled in the art should understand that the technical solutions described in the above embodiments can still be modified or some or all of the technical features thereof can be equivalently replaced. However, the modifications or replacements do not cause the essence of the corresponding technical solutions to deviate from the scope of the technical solutions of the embodiments of the disclosure. As long as the features of various embodiments do not violate the inventive spirit nor conflict with each other, the features can be mixed and matched arbitrarily.

What is claimed is:

1. An electronic device, comprising:
a substrate;
a gate line, disposed on the substrate; and
a switch element, disposed on the substrate and electrically connected to the gate line; and
a photodetector, disposed on the substrate and electrically connected to the switch element, wherein the photodetector comprises a first semiconductor,
wherein in a cross-sectional view of the electronic device, one sidewall of the first semiconductor and the gate line are spaced from each other by a first distance, and the first distance is greater than or equal to 2 micrometers and less than or equal to 6 micrometers.

2. The electronic device according to claim 1, wherein the first distance is greater than or equal to 3 micrometers and less than or equal to 5 micrometers.

3. The electronic device according to claim 1, further comprising:
a conductive wire and a first insulation layer, wherein the conductive wire is electrically connected to the photodetector, the first insulation layer is disposed between the photodetector and the conductive wire, and a thickness of the first insulation layer is greater than or equal to 0.5 micrometer and less than or equal to 3 micrometers.

4. The electronic device according to claim 3, wherein the thickness of the first insulation layer is greater than or equal to 1 micrometer and less than or equal to 2.5 micrometers.

5. The electronic device according to claim 3, wherein the conductive wire intersects with the gate line.

6. The electronic device according to claim 3, wherein the first insulation layer has an opening, and the conductive wire is electrically connected to a first electrode of the photodetector through the opening of the first insulation layer.

7. The electronic device according to claim 1, wherein the photodetector detects an intensity of electromagnetic wave and generates an electrical signal, and the switch element receives the electric signal.

8. The electronic device according to claim 1, wherein the photodetector further comprises a first electrode and a second electrode, the first semiconductor is disposed between the first electrode and the second electrode, in the cross-sectional view of the electronic device, at least one of the first electrode and the second electrode is spaced from the one sidewall of the first semiconductor by a second distance, and the second distance is greater than or equal to 0.5 micrometer and less than or equal to 6 micrometers.

9. The electronic device according to claim 8, wherein the second distance is greater than or equal to 1.5 micrometers and less than or equal to 4.5 micrometers.

10. The electronic device according to claim 8, wherein the first semiconductor of the photodetector is electrically connected to a source electrode of the switch element through the second electrode.

11. The electronic device according to claim 8, further comprising:
a second insulation layer, disposed on the second electrode, wherein the first semiconductor is disposed on the second insulation layer, the second insulation layer has a first surface and a second surface opposite to the first surface, and in the cross-sectional view of the electronic device, an included angle between the first surface and the second surface is greater than 0 degree and less than or equal to 12 degrees.

12. The electronic device according to claim 11, wherein the included angle between the first surface and the second surface is greater than 2 degrees and less than or equal to 10 degrees.

13. The electronic device according to claim 11, wherein in the cross-sectional view of the electronic device, an intersection between the first surface and the second surface is spaced from an edge of the second electrode by a third distance, and the third distance is greater than or equal to 2 micrometers and less than or equal to 5.5 micrometers.

14. The electronic device according to claim 11, wherein the second insulation layer has an opening, and the first semiconductor is electrically connected to the second electrode through the opening.

15. The electronic device according to claim 1, further comprising:
a scintillator, wherein in a top view of the electronic device, the scintillator and the photodetector are overlapped.

16. The electronic device according to claim 1, wherein the photodetector is disposed between the scintillator and the substrate.

17. The electronic device according to claim 1, wherein the switch element is a transistor.

18. The electronic device according to claim 1, wherein the switch element comprises a gate electrode, a second semiconductor, a source electrode, and a drain electrode, the gate electrode is disposed on the substrate, the second semiconductor is disposed on the gate electrode, the source electrode and the drain electrode are respectively disposed on the second semiconductor, and the source electrode and the drain electrode are electrically connected to the second semiconductor, respectively.

19. The electronic device according to claim 1, further comprising:
another gate line, disposed on the substrate and parallel to the gate line,
wherein in the cross-sectional view of the electronic device, the other sidewall opposite to the one sidewall of the first semiconductor is spaced from the another gate line by another first distance, and the another first distance is greater than or equal to 2 micrometers and less than or equal to 6 micrometers.

20. The electronic device according to claim 19, wherein the another first distance is greater than or equal to 3 micrometers and less than or equal to 5 micrometers.
